(19) United States
(12) Patent Application Publication
(10) Pub. No.: US 2015/0371925 A1
(43) Pub. Date: Dec. 24, 2015

(54) THROUGH ARRAY ROUTING FOR NON-VOLATILE MEMORY

(71) Applicant: Intel Corporation, Santa Clara, CA (US)

(72) Inventors: Deepak Thimmegowda, Boise, ID (US); Roger Lindsay, Boise, ID (US); Minsoo Lee, Boise, ID (US)

(73) Assignee: Intel Corporation, Santa Clara, CA (US)

(21) Appl. No.: 14/310,391

(22) Filed: Jun. 20, 2014

(51) Int. Cl. H01L 23/48; H01L 27/115; H01L 21/768

(52) U.S. Cl. CPC H01L 23/481; H01L 21/76879; H01L 21/76843; H01L 27/11551

(57) ABSTRACT

Technologies for routing access lines in non-volatile memory are described. In some embodiments the technologies include forming one or more through array vias in a portion of a memory array in a non-volatile memory, such as in an array region or peripheral region, one or more access lines may be routed through the through array via, instead of within a region above or below an array or peripheral region of the memory array. This can enable alternative routing configurations, and may enable additional access lines to be routed without increasing or substantially increasing the block height of the non-volatile memory. Non-volatile memory employing such technologies is also described.

### FIELD

The present disclosure generally relates to technologies for routing one or more channels/lines used in non-volatile memory. More particularly, present disclosure generally relates to technologies in which one or more channels used in non-volatile memory are routed through a via produced in a memory array that enables access to underlying circuitry. Memory including such technologies and methods of making such vias are also described.

### BACKGROUND

Many types of semiconductor memory are known in the art. Some memory types are volatile and will lose their contents if power is removed. Other memory types are non-volatile and retain information stored therein even if power to the memory is removed. Flash memory is one type of non-volatile memory. In general, flash memory stores charge in a charge storage region of a memory cell. In a floating gate flash cell, a conductive floating gate positioned between a control gate and a channel of a metal oxide semiconductor field effect transistor (MOSFET) may be used to store a charge. In a charge trap flash (CTF) cell, a layer of non-conductive material such as a nitride film may be used to store charge between the control gate and the channel of the MOSFET. The voltage threshold of the MOSFET-based flash cell may be changed by altering the amount of charge stored in the charge storage region of the cell, and the voltage threshold can be used to indicate a value that is stored in the cell.

One architecture that is commonly used in flash memory is the NOT AND (NAND) architecture. In a typical NAND architecture two or more flash cells are coupled together source to drain, so as to form a string of memory cells. The control gates of the individual cells are coupled to access (e.g., global control) lines, such as word lines. Select gates (e.g., select gate source (SGS), select gate drain (SGD), etc.) may be MOSFETs that are coupled to either end of a NAND string, and couple the NAND string to a source line at one end of the string and to a data (e.g., bit) line at the other end.

Some NAND flash devices are include stacks of flash memory cells that may be stacked vertically (e.g., in vertical NAND) and optionally in a three dimensions (e.g., in 3D NAND). In either case, such devices may include a stack of flash memory cells that include a source, drain and channel that are arranged vertically so that the cells are positioned one on top of the other to form a vertical NAND string. The vertical NAND string may be positioned on top of a select gate (e.g., a select gate drain (SGD), select gate source (SGS), etc.), and another select gate (e.g., SGD, SGS) may be positioned on top of the vertical NAND string.

To meet demands for higher capacity memory designers continuously strive to increase memory density, i.e., to increase the number of memory cells that are present in a given area of an integrated circuit die. One way of increasing memory density is to decrease the feature size of individual memory cells and thus the overall size of the cells themselves. Although this can increase the number of memory cells that may be included in a specified area, reducing the feature size of a memory cell may increase the risk of device failure and charge leakage. Another mechanism to increase memory density is to form vertical NAND strings as noted above. In such instances memory density may be practically limited by block size considerations, which may be imposed by a design, a standard, or come combination thereof. Like traditional (e.g. planar) NAND devices, the density of vertical NAND may be increased by reducing the feature size of memory cells within each vertical NAND string.

In any case increasing the density of memory cells within a NAND memory array can make it challenging to route the various access (e.g. word) lines, data (e.g., bit) and other (e.g., source, drain etc.) lines/channels that may be used in the device. This is particularly true when design considerations and/or a standard limit the block height of the device. As will be described below the technologies of the present disclosure aim to address various aspects of such challenges, e.g., by enabling alternative routing configurations for non-volatile memory devices such as vertical and/or 3D NAND devices.

### BRIEF DESCRIPTION OF THE DRAWINGS

Features and advantages of embodiments of the claimed subject matter will become apparent as the following Detailed Description proceeds, and upon reference to the Drawings, wherein like numerals depict like parts, and in which:

FIG. 1 illustrates a cross sectional view of memory cells of one example memory array consistent with the present disclosure.

FIG. 2A is one view of an example routing diagram for a memory array of a non-volatile memory;

FIG. 2B is another view of an example routing diagram for a memory array of a non-volatile memory;

FIG. 3 is an example routing diagram for a memory array of a non-volatile memory consistent with the present disclosure;

FIG. 4 is a flow diagram of one example method of forming a through array channel consistent with the present disclosure;

FIGS. 5A-5F stepwise illustrate one example method of forming a through array channel consistent with the present disclosure.

FIG. 6 is a simplified block diagram of one example of a memory device coupled to a house as part of an electronic system in accordance with the present disclosure.

### DETAILED DESCRIPTION

In the following description reference is made to the accompanying drawings that form a part of the instant description, and which illustrate various example embodiments. It is emphasized that the illustrated embodiments are for the sake of example only, and that embodiments other than those depicted are envisioned by and included in the present disclosure. Such other embodiments may include structure, logical, and electrical changes relative to the illustrated embodiments, which may be made without departing from the scope of the present disclosure.

In the context of the present disclosure the term “semiconductor” should be understood to refer to any semiconductor structure, including but not limited to those in the form of a layer of material, a wafer, or a substrate. Without limitation, the term “semiconductor” may be understood to encompass silicon on sapphire (SOS) technology, silicon on insulator (SOI) technology, thin film transistor (TFT) technology, doped and undoped semiconductors, epitaxial layers of a silicone supported by a base semiconductor structure, other semiconductor structures known to one skilled in the art, combinations thereof and the like. It should also be understood that when the term “semiconductor” is used herein, various processing steps may have been performed to form regions, junctions, etc. within the structure of the semiconductor.

As used herein, directional adjectives should be understood to be relative to the surface of a substrate upon which a feature (e.g., a memory cell) is formed. For example a vertical structure should be understood to extend away from the surface of a substrate on which the structure is formed, with the bottom end of the structure being proximate the surface of the substrate. It should also be understood that a vertical structure need not be perpendicular to the surface of the substrate on which it is formed, and that vertical structures include structures that may be formed to extend at an angle relative to the substrate.

The drive to increase the density of non-volatile memory has lead memory designers to increase the number of memory cells in a given area of a memory device. As memory density has increased it has become increasingly difficult to route the various access, data and other lines that may be needed to run the device without undesirably affecting device performance. Although it is possible to add additional routing channels for such lines to a non-volatile memory, e.g., above or below a memory array, it may be necessary to increase the block height of the device to accommodate such channels. In instances where the block height is limited, e.g., by design considerations, a standard, etc., increasing the block height may not be permitted or may otherwise be undesirable.

The present disclosure aims to address this issue by providing technologies that enable alternative mechanisms for routing one or more of the access, data and/or other lines that may be used in non-volatile memory. In general, the technologies described herein enable alternative mechanisms for routing of one or more lines from contacts/traces that are above a memory array to one or more contacts below a memory array, such as contacts of string driver circuitry or other supporting circuitry (e.g. complementary metal oxide semiconductor (CMOS) circuits) that may be provided by CMOS under array (CUA) technology. More particularly, the technologies described herein leverage the use of one of more vias which may be formed through a portion of a memory array, e.g., in an array region and/or a peripheral region thereof, so as to enable access to regions/circuitry that may be formed under the array. One or more channels may be formed in such vias and filled with conductive material to enable electrical coupling of various lines to circuitry formed under a memory array.

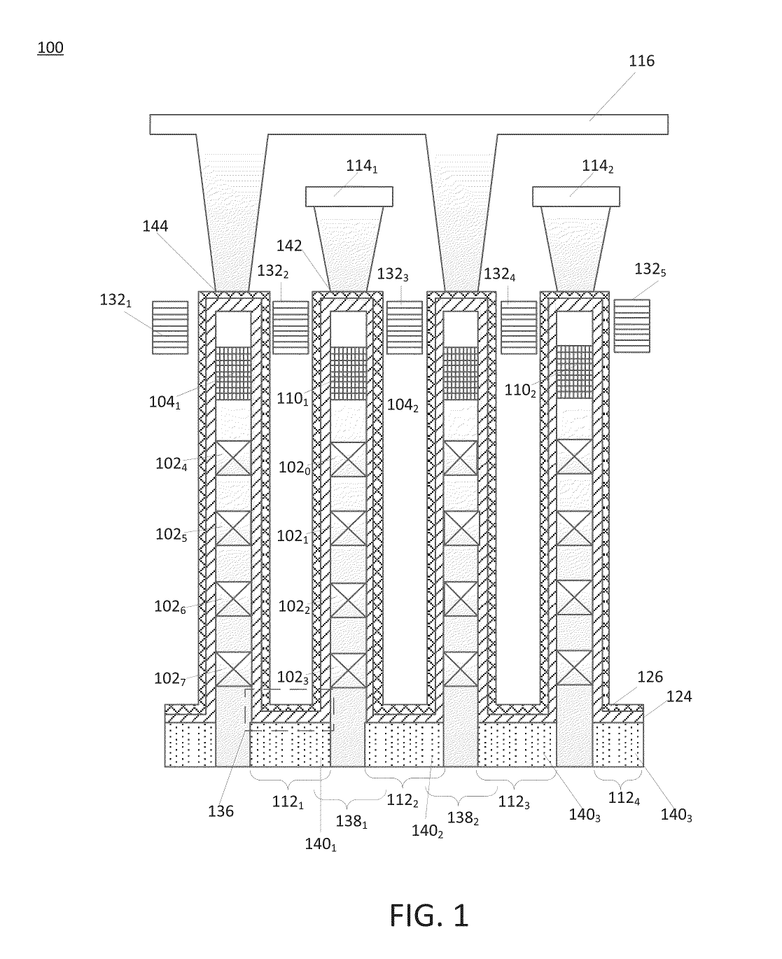

Reference is now made to FIG. 1, which illustrates a cross sectional view of memory cells of one example memory array consistent with the present disclosure. As shown, memory array 100 (hereinafter, “array 100”) includes a plurality of memory cells that are formed in a plurality of memory strings 112_{1 . . . 4}, which are arranged in a NAND configuration. FIG. 1 may therefore be understood to depict memory cells of one example NAND memory device consistent with the present disclosure. As illustrated, the memory 100 include select gate source (“SGS”) gates 110 and select gate drain (“SGD”) gates 104, each of which is coupled to one or memory strings 112_{1 . . . 4}. SGS 110 may be controlled by a SGS control line and SGD 104 may be controlled by an SGD control line (both not shown). In general, SGD 104 and SGS 110 may be biased during the performance of one or more operations with memory 100 (e.g., read operations, write operations, erase operations etc.) so as to activate or deactivate memory cells or strings thereof during such operations, either alone or in combination with controlled biasing of string select gate 132, which is described below.

Strings 112_{1 . . . 4} in this embodiment are formed in a folded arrangement such that a portion of each string is formed with a first portion formed along a first column 138₁ and a second portion of the same string is formed alone an adjacent (e.g. second) column 138₂. In this regard, “columns” 138₁, 138₂ may be understood to encompass strings of memory cells that are arranged in a NAND string.

Strings 112_{1 . . . 4} are arranged in a folded (e.g., U-shaped) arrangement and may include a plurality (e.g., 8, 16, 32, etc.) of memory cells. By way of example, strings 112_{1 . . . 4} may each include eight (8) memory cells where four memory cells are formed along one vertical column (e.g., column 112₁) and four memory cells are formed along an adjacent memory column (e.g., column 112₂), thus forming a U-shaped arrangement. The NAND memory devices of the present disclosure may include two of more of such U-shaped strings that are formed adjacent to one another. Memory 100 may also include a string select gate (SSG) 132, which may be formed between each end of strings 112_{1 . . . 4}.

As further shown in FIG. 1, in various embodiments strings 112_{1 . . . 4} may be coupled between a data (e.g. bit) line 116 and two source lines 114_{1,2}, e.g., at bit line contact points 144 and source line contact points 142. Coupling of a string to a bit line may be controlled by SSG 132, which may be a conductor such as polycrystalline silicon (polysilicon). In general, SSG 132 may be biased (activated) to couple and/or decouple a first end of a selected string 112_{1 . . . 4} to data (bit) line 116 and another end of the selected string to a source line 114_{1, 2}.

It should be understood that only a portion of memory 100 and strings 112_{1 . . . 4} are shown in FIG. 1, and that the non-volatile memories of the present disclosure are not limited to the configuration shown. Indeed, memory 100 may include an array of memory cells that include more or less NAND strings than those identified in FIG. 1 as strings 112_{1 . . . 4}. Moreover each string may include more or less than eight memory cells, any or all of which may be coupled by word lines 102_{0 . . . 7} or other word lines (not shown). For example, additional memory cell structures (not shown) might be located within each of strings 112_{1 . . . 4} and/or one or more additional strings. Such additional memory cells may include active or inactive (dummy) memory cells, such as those described in U.S. Pre-Grant Publication No. 2009/0168519. Indeed in some embodiments the memories described herein may be NAND memory that includes a memory array having 2ⁿ memory cells, where n is an integer.

As further depicted in FIG. 1, memory 100 may further include charge storage structure 124 and channel structure 126. Charge storage structure 124 may be in the form of one or more continuous layers that are formed through memory strings 112_{1 . . . 4}, as shown. In some embodiments, charge storage structure 124 may include a first oxide layer, a nitride layer formed on the first oxide layer, and a second oxide layer formed on the nitride layer (all not shown).

Memory 100 may also include a plane gate, which in FIG. 1 is illustrated as including a plurality of control gates 140_{1 . . . 4}, each of which may be formed under a string of memory cells 112_{1 . . . 4}. Without limitation, control gates 140_{1 . . . 4} may form part of circuitry under memory array 112_{1 . . . 4} which may be used to drive memory strings 112_{1 . . . 4}. Accordingly, control gates 140_{1 . . . 4} may form part of word line driver circuitry that may be formed under memory strings 112_{1 . . . 4}, and which may be produced by any suitable technology such as CMOS under array technology.

Although not illustrated, the memory cells of memory 200 may be arranged in three dimensions (3D) so as to form a 3D array of memory cells. For example, the memory cells SGS 110₁₋₂, SGD 104₁₋₂ and string select gates (“SSG”) 132_{1 . . . 5} may be repeated both behind (e.g., below) and in front (e.g., above) the plane shown in FIG. 1. The control lines for such gates may also extend in front of and below the plane of FIG. 1. More specifically, word lines 102_{0 . . . 7} (which may include the access line and locally the control gate structure of each memory cell) may be understood in such embodiments to pass into and out of the plane of the memory cell array of memory 100. Similarly SGD 104₁₋₂ SGS 110₁₋₂, and SSG 132_{1 . . . 5} (which may each function as a control structure locally in each of strings 112_{1 . . . 4}) may also include a control signal line passing through the plane of FIG. 1. The plane gate (e.g. control gates 140_{1 . . . 4}) may also be repeated within the 3D array.

It is noted that FIG. 1 has been provided to illustrate one configuration of a NAND memory array that may be used in accordance with the present disclosure. It should be understood that the present disclosure envisions the use of various different types of non-volatile memory, including NAND memory that is configured in a manner other than memory 100 of FIG. 1, as well as memory having a NOT OR (NOR) architecture. In any case, further information regarding memory 100 and methods of forming such memory may be found in U.S. Pat. No. 8,681,555, the entire content of which is incorporated herein by reference.

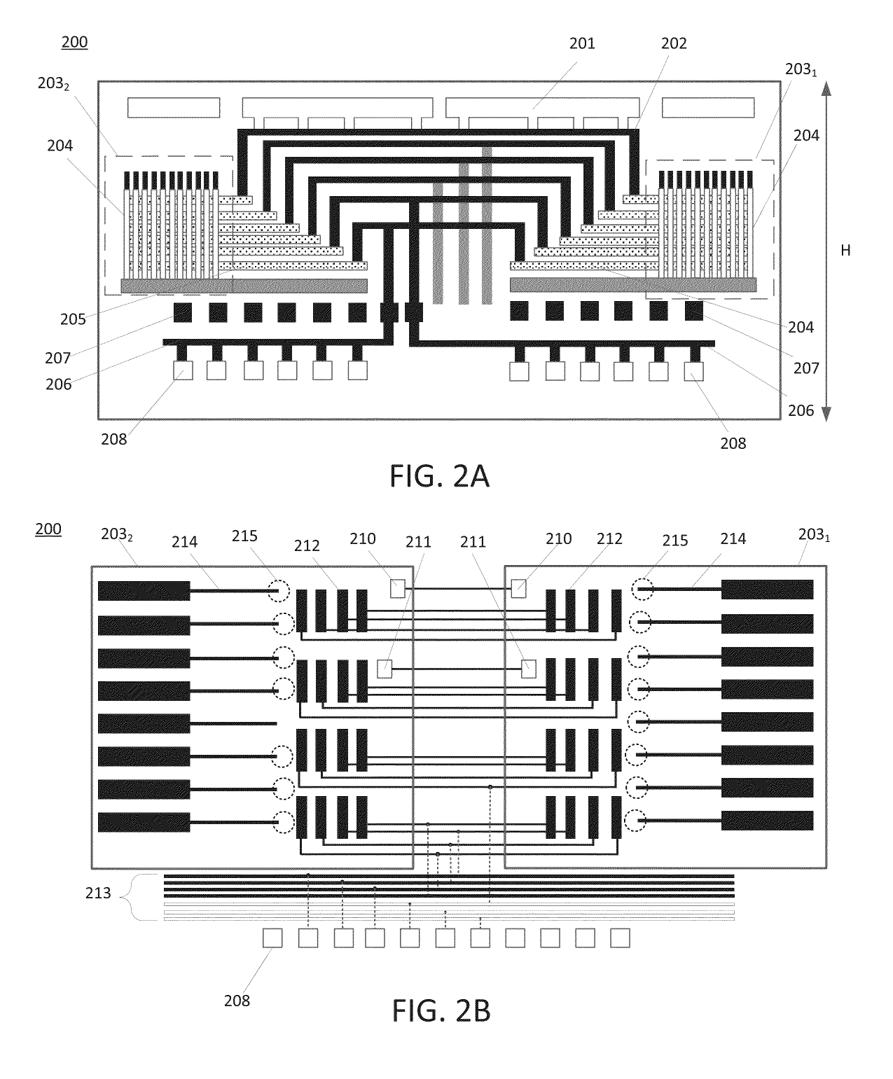

Reference is now made to FIGS. 2A and 2B, which provide different views of an access line routing scheme for a memory array of a non-volatile memory consistent with the present disclosure. As used herein, the terms “access line,” “control line,” and routing line are interchangeably used to refer to lines which may be used to transmit signals to and/or from one or more components of a non-volatile memory. Access/control lines may therefore include lines/channels which may be used to transmit signals to and from one or more gates (e.g., select gate source, select gate drain, etc.), one or more word lines, one or more memory cells, driving circuitry, combinations thereof and the like, which may be used in a non-volatile memory. As may be appreciated, access lines may be routed through one or more channels formed in a non-volatile memory.

It is further noted that for the sake of illustration the routing diagrams of FIGS. 2A and 2B illustrate an example in which a non-volatile memory includes multiple memory arrays (tiles) which include memory strings that may be driven by underlying driver circuitry that is shared by each memory array. As such, FIGS. 2A and 2B may be understood to depict different views of a routing diagram for a non-volatile memory (e.g. a vertical NAND memory) which employs a common word line driver architecture that may for example be provided under the respective memory arrays by CUA technology. One purpose of FIGS. 2A and 2B is to illustrate various challenges that may be encountered in the routing of various access, data, etc. lines that may be used in such a device. It is emphasized that this illustration is exemplary only, and that the technologies described herein may be employed with any suitable non-volatile memory.

As shown in FIGS. 2A and B, memory 200 may include a plurality of memory arrays (tiles). This concept is illustrated in FIG. 2, which depicts memory 200 as including first memory array (tile) 203₁ and second memory array tile 203₂. Each of memory arrays (tiles) 203₁, 203₂ may be in the form of a vertical array of memory cells, such as may be used in a vertical or 3D NAND architecture. As such, memory arrays 203₁, 203₂ may each include and/or be coupled to a plurality of corresponding channels 204, each of which may be accessed/or controlled with one or more access (word) line plates 205. Word line plates 205 may be coupled to conductive (e.g., metal, polysilicon, etc.) channels (routing lines) 202, which in turn may be coupled to conductive interconnects 201 disposed in a region above memory arrays 203_{1,2}. To facilitate connection and routing of conductive channels (lines) 202, word line plates 205 may be formed in a tiered structure as shown in FIG. 2A. Conductive channels 202 may also couple word line plates 205 to one or more access (word) control lines, e.g., via word line contacts 212. The foregoing concept is illustrated in FIG. 2A, which shows conductive lines 202 as coupling to first word control lines 206 and/or second word control lines 207, which in this case are located in a region below memory arrays 203_{1,2}. Memory 200 may further include interconnects 209, which may include conductive material and may function to electrically couple two or more of conductive lines 202 and/or other components of memory 200 to one another.

First and/or second word control lines 206, 207 may be coupled to driver circuitry 208, as shown in FIGS. 2A and B. As noted above, driver circuitry 208 may be shared between memory arrays 203_{1,2}, and may function to drive memory strings thereof. Driver circuitry 208 may therefore in some embodiments be configured in the form of a common word line driver architecture, e.g., which may be provided under memory arrays 203_{1, 2} via CUA technology or some other method. As shown in FIG. 2B, first and/or second word control lines 206, 207 may include, be in the form of, and/or couple to circuitry routing channels 213, which may include conductive lines (e.g., of or including metal, polysilicon, or the like) that enable electrical contact with driver circuitry 208.

As also shown in FIG. 2B, memory 200 may include source channels 210, SGS lines 211 and SGD lines 214. Source channels 210 may be formed of or include one or more lines including conductive material (e.g., metal, poysilicon, etc.) and may function to couple one or more features of memory 200 to a source. Similarly, SGS lines 211 and SGD lines 214 may be formed of or include conductive material (again, metal, polysilicon, etc.) and may respectively function to couple corresponding SGS and SGD gates to driver circuitry 208 or other suitable components.

As can be seen from FIGS. 2A and 2B, the various lines and channels used in memory 200 may be routed within block height H. In the illustrated embodiments for example, word lines 206, 207, source lines 210, SGS lines 211, and SGD lines 214 may be coupled to conductive lines 202 and/or interconnects 209, some or all of which may be routed to driver circuitry 208. More particularly, one or more of such access lines may be routed above or below memory arrays 203_{1,2}, i.e., within the block height H of memory 200. Although routing in this manner can be effective, as memory density increases, additional access lines may be needed. Routing of the additional access lines may be hindered or prevented when block height H is limited, e.g., by design considerations and/or a standard that defines a maximum block height. This concept is illustrated in FIG. 2B, which depicts SGD lines 214 as lacking a connection to driving circuitry 213, e.g., in region 215. As noted above SGD lines 214 could be routed above or below memory arrays 203₁ or 203₂, but doing so may entail increasing block height H, which may be undesirable.

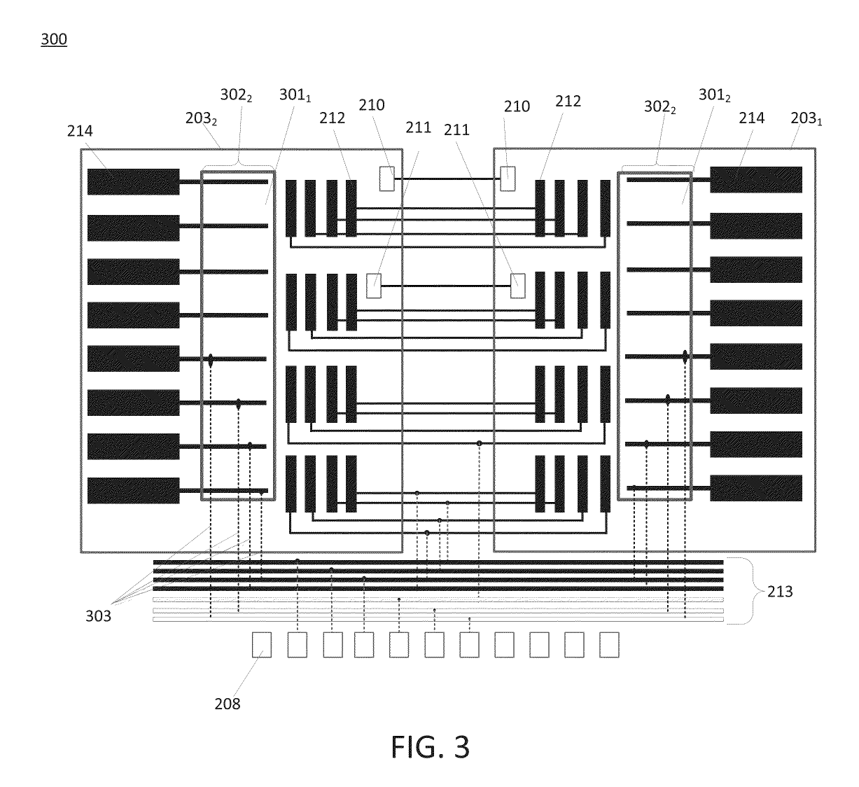

Reference is therefore made to FIG. 3, which depicts an alternative routing diagram for a non-volatile memory consistent with the present disclosure. As shown, memory 300 includes many of the same components as memory 200 of FIGS. 2A and B. As the nature and function of such elements is the same in FIG. 3 as it is in FIGS. 2A and B, such elements are not described again for the sake of brevity. With this in mind, memory 300 differs from memory 200 in that it includes through array via regions 301₁, 301₂, which may be formed in corresponding portions 302₁, 302₂ of memory 300. In some embodiments, one or both of portions 302₁, 302₂ may correspond to an array region of memory 300, i.e., a region of memory 300 which is at least partially occupied by a memory array, e.g., memory array 203₁, 203₂ of FIG. 2A (not shown in FIG. 3). Alternatively, one or both of portions 302₁, 302₂ may correspond to a peripheral region of memory 300, i.e., a region of memory 300 that may be formed outside of and/or around a memory array region. In some embodiments, a non-volatile memory may have a total memory area A, and the term “array region” may refer to a region within area A that is occupied by a memory array. In such instances the term “peripheral region” may refer to a region of area A that is outside the array region and which may extend from an edge of the array region to a distance that is about 30% (e.g., about 25%, about 20%, about 15%) of area A. In some embodiments, the peripheral region of a non-volatile memory extends from greater than 0 to about 25% of the total memory area A.

Without limitation, in some embodiments one or both of portions 302₁, 302₂ correspond to a peripheral region of memory 300. In any case one or more through via channels 303 may be formed in through via regions 301₁, 302₂, so as to couple one or more channels and corresponding access lines of memory 300 to driver circuitry 208. For example, in the illustrated embodiment SGD lines 214 may be coupled to driver circuitry 208 or other components of memory 300 by through via channels 303.

It is noted that for the sake of illustration and ease of understanding, FIG. 3 illustrates a routing diagram in which SGD lines 214 may be coupled to driver circuitry 208 or other components of memory 300 by through via channels 303. It is emphasized that the illustrated example is illustrative only, and that one, all or a combination of the access lines for memory 300 (or 200) may be coupled to appropriate components by one or more through via channels 303 formed in through via region 302₁, 302₂. Indeed in some embodiments one or more through via channels 303 may be used to route SGD lines 214, circuitry routing channels 213, SGS lines 211, source channels 210, word control lines 206, 207, combinations thereof and the like to appropriate components of memory 300.

As may be appreciated, routing of various non-volatile memory access lines with through via channels 303 may bypass a stack of word line plates that may be used in memory 300, such as but not limited to the tiered stack or word line plates 205 in memory 200 of FIG. 2B. This may allow access to driving circuitry 208 and/or the routing of additional access lines without the need to increase block height H, and potentially without the need to form and use additional interconnects to route around other components of a memory device. More generally the use of through array vias 303 opens up avenues to a variety of alternative routing schemes, which may exhibit one or more benefits relative to other routing schemes that rely on routing of various channels above and/or below a memory array.

It is again noted that FIGS. 2A, 2B and 3 illustrate routing schemes as they may be configured for use non-volatile memory that has a specific memory array configuration, layout, and underlying driving circuitry. It is again emphasized that such illustrations are for the sake of example only, and that the technologies described herein may be used to enable alternative routing methodologies for a wide array of different non-volatile memory configurations, including but not limited to vertical and 3D NAND configurations. Indeed the present disclosure should be construed to broadly relate to the use of through array channels/lines and associated vias to perform routing functions in any suitable type of non-volatile memory.

Therefore in some embodiments the present disclosure relates to a NAND memory including an array region and a peripheral region, wherein at least one array of vertical memory strings (e.g., vertical and/or 3D NAND) is formed in the array region and above above driving circuitry (e.g., string d3riving circuitry) for the at least one array, wherein the non-volatile memory further includes at least one through array via region that includes at least one through array channel that is configured to electrically couple at least one access line to the driving circuitry or another suitable component of the memory. In this context, an “access” line means one or more of the control lines (SGS, SGD), source line, drain line, word line, etc. which may be used in a non-volatile memory.

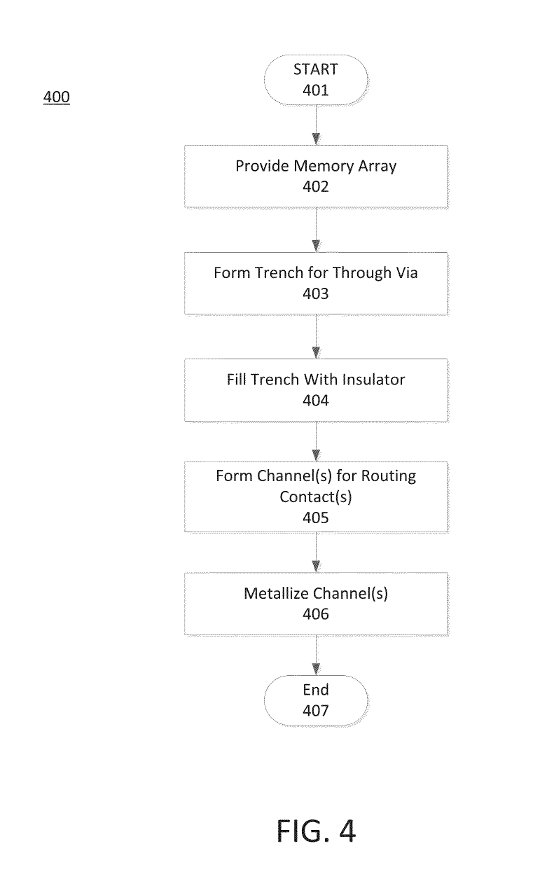

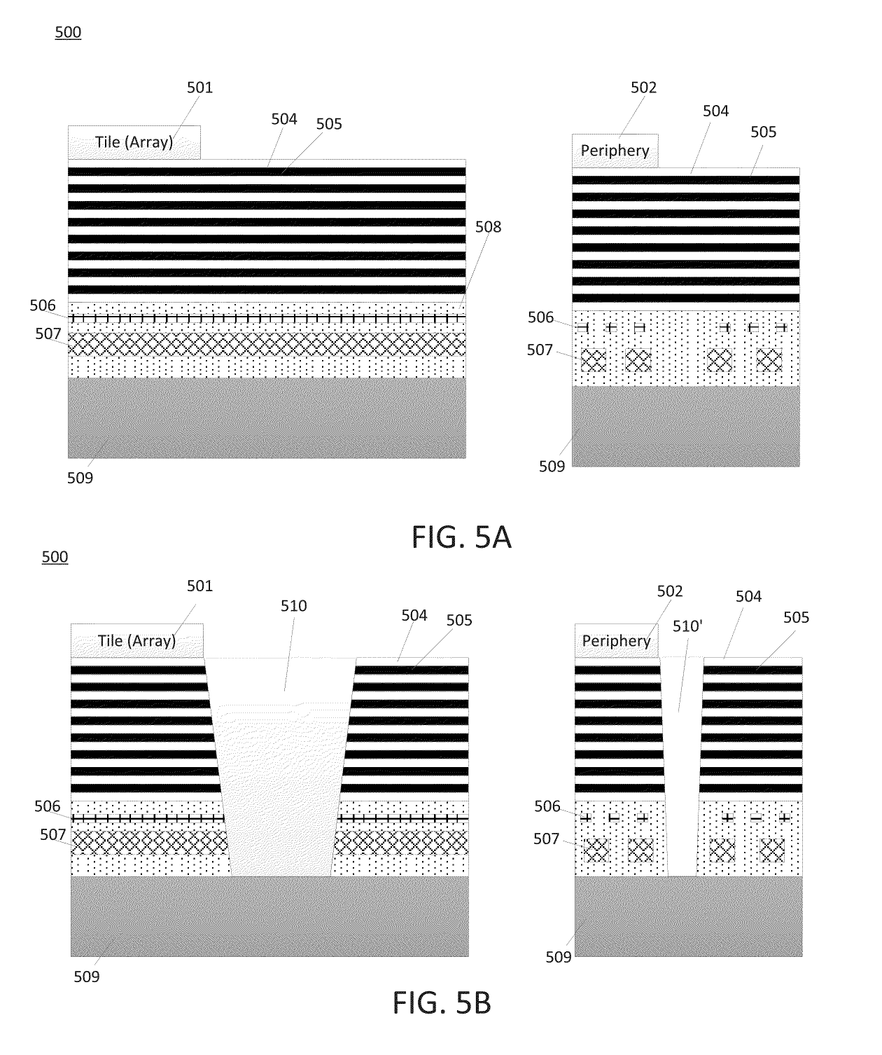

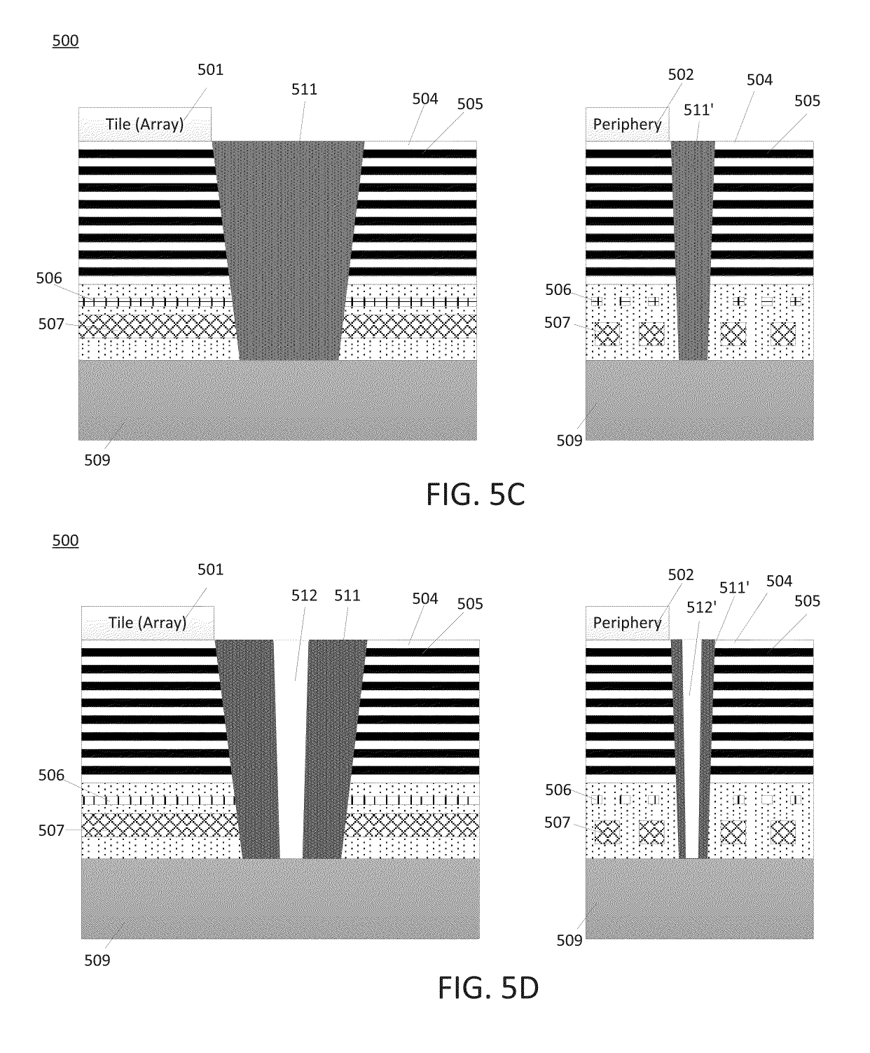

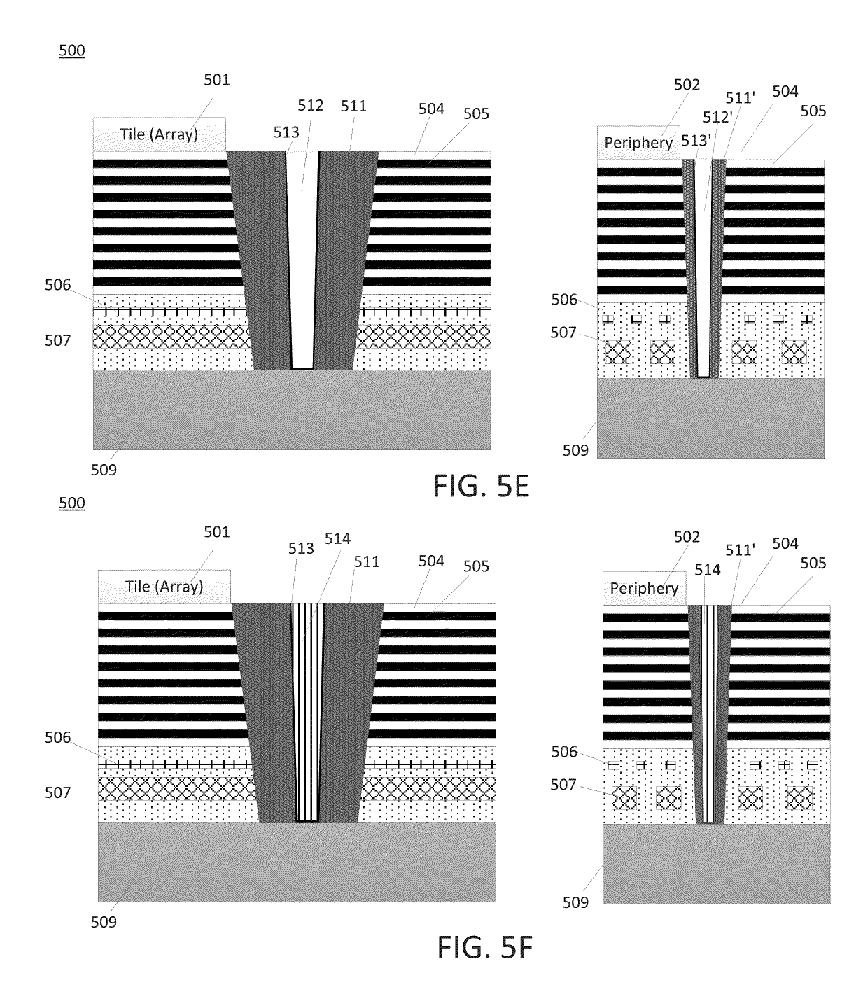

With the foregoing in mind, another aspect of the present disclosure relates to through array channels for non-volatile memory and methods of making the same. In this regard reference is now made to FIG. 4, which is a flow chart of operations that may be performed in accordance with one example method of making a through array channel consistent with the present disclosure. For the sake of clarity and illustration, the operations of FIG. 4 will be described in conjunction with FIGS. 5A-5F, which stepwise illustrate the formation of an example through array channel consistent with the present disclosure in an array region and a peripheral region of a NAND. While the present disclosure focuses only on the formation of a through array via, it should be understood that the through array vias consistent with the present disclosure may be formed before, after, or during the formation of other components of a non-volatile memory, including one or more memory arrays, control gates, sources, drains, access lines etc. thereof. Without limitation, the through array channels described herein are preferably formed in the course of other process operations that may be used to provide one or more other components of a non-volatile memory, e.g., so as to avoid or limit the need for additional or different masking, deposition, cleaning or other processing steps.

As shown in FIG. 4 method 400 starts at block 401. The method may then proceed to block 402, wherein a memory array of a non-volatile memory may be provided, e.g., on a wafer or otherwise. The memory array may include an array region and a peripheral region, as described above. This concept is illustrated in FIG. 5A, which depicts array region 501 and peripheral region 502 of a portion of memory array 500. As shown, array region 501 and peripheral region 502 may include alternating dielectric layers 504 and conductive layers 505. Dielectric layers 504 may be formed from or include any suitable dielectric material, including but not limited to dielectric nitrides and dielectric oxides such as silicon oxide (SiOₓ) and aluminum oxide. Likewise conductive layers 505 may be formed from or include any suitable conductive material, such as but not limited to polycrystalline silicon (polysilicon), one or more metals and/or metal nitrides such as titanium nitride, combinations thereof and the like.

Alternating dielectric and conductive layers 504, 505 may be grown or deposited on insulating layer 508, which itself may be grown or deposited on or above structure 509. Insulating layer 508 may be formed from or include a dielectric and/or insulating oxide material, such as but not limited to silicon oxide. As shown in FIG. 5A, one or more routing lines such as first and second routing lines 506, 507 may be formed in insulating layer 508. First and second routing lines may be any suitable routing lines that may be employed in a non-volatile memory, such as one or more source channels, word line channels, SGS lines, SGD lines, etc. Of course consistent with the foregoing description, routing lines 506, 507 may be omitted, e.g., in instances where such lines may be routed through other portions of memory array 500, e.g. using a through via channel consistent with the present disclosure. However for the sake of example routing lines 506, 507 are depicted within insulating layer 508 to illustrate how the through array channels described herein may be formed so as to avoid interfering with routing lines and other components within insulating layer 508 or any other portion of memory array 500. As will be discussed later, the through array channels described herein are preferably formed so as to be isolated from or otherwise avoid routing lines and/or other components that may be within memory array 500, such as but not limited to routing lines 506, 507 that may be within layer 508.

Structure 509 may be a conductive substrate or other structure (e.g., a bond pad, conductor line, etc.), which may function to electrically couple a through array channel consistent with the present disclosure to another component of a non-volatile memory, such as driving circuitry that may be formed under memory array 500, e.g., by CUA technology as described above. In this regard any suitable conductive material may be used to form structure 509, in including but not limited to metals such as tungsten, copper and aluminum, as well as other conductive materials such as polysilicon. Without limitation, structure 509 is preferably in the form of a bond pad or conductive line that is formed from a metal such as tungsten.

Returning to FIG. 4, the method may proceed to block 403, wherein one or more trenches may be formed in the memory array. This concept is illustrated in FIG. 5B, which depicts the formation of trenches 510, 510′ in array region 501 and peripheral region 502 of memory array 500, respectively. Trenches 510, 510′ may be formed via any suitable trench forming process known in the art, such as but not limited to wet chemical etching, dry etching, photolithography, combinations thereof, and the like. Without limitation, one or more of trenches 510, 510′ may be preferably formed using a dry etching process such as a high aspect ratio trench (HART) dry etching process. HART dry etching processes are well understood in the art, and therefore a detailed description thereof is not provided herein. In some embodiments, the HART dry etching process may employ a dry etchant that may aggressively etch the materials for dielectric layers 504 (e.g., SiOₓ), conductive layers 505 (e.g., polysilicon), layer 508 (e.g., SiOₓ) and (optionally) routing lines 506, 507, but which may not etch or may not aggressively etch the material of structure 509 (e.g., metals such as tungsten). As a result, the dry etching process may produce a trench that extends from an upper surface of array region 501 and peripheral region 502 to structure 509. Trenches 510, 510′ may therefore provide access there through to structure 509.

It is noted that for the sake of illustration FIGS. 5B-5F stepwise depict an embodiment wherein a single trench is formed in both the array region and peripheral region of a non-volatile memory, and in which a single channel is formed in the trench. It should be understood that such an embodiment is but one non-limiting example of the present disclosure, and that the technologies described herein may be used to form one or more trenches in only an array region of a memory array, only a peripheral region of a memory array, in both the array and peripheral regions of such an array, and/or in one or more of the peripheral and array regions as well as some other region of the memory array or a non-volatile memory device including the memory array. Therefore in some embodiments the non-volatile memories described herein may include a memory array having a peripheral region and an array region, wherein one or more (e.g., 2, 3, 4, 5, 6 etc.) trenches may be formed in at least one of the peripheral and array regions, and optionally in another region of the array or device including the array. Moreover, each trench may be subsequently processed to include one or a plurality of through array channels.

In FIGS. 5B-5F trenches 510, 510′ are illustrated as having a tapered structure, such that a dimension (e.g., width) proximate the bottom of the trench is smaller than the corresponding dimension proximate the top of the trench. As such, trenches 510, 510′ may be understood to have a sidewall exhibiting a slope. The magnitude of the slope of the sidewalls of trenches 510, 510′ may vary widely, and may be dictated by design and/or processing constraints. Without limitation, the slope of one or both of the sidewalls of trenches 510, 510′ may range from about 85 to about 90 degrees relative to the plane of the upper surface of structure 509, such as about 87 to 89 degrees or even about 88 to about 89 degrees. As may be appreciated, the slope of the sidewalls of trenches 510, 510′ may be selected so as to provide a desired level of electrical isolation between conductive materials which may be added to trench 510, 510 (e.g., barrier layer 513, 513′ and conductive materials 514, 514′ described below). However, an excessively high slope may make it difficult to fill trenches 510, 510′ without gaps or other defects.

In some embodiments trenches 510, 510′ may be positioned such that they avoid or otherwise do not affect the function of other components of a memory array, such as routing lines 506, 507 which may be present in layer 508. This concept is shown in the peripheral aspect if FIG. 5B, which depicts trench 510′ as being formed so as not to impinge on routing lines 506, 507, e.g., as being formed between such routing lines.

Again returning to FIG. 4, the method may then proceed to block 404, wherein the trench(es) formed pursuant to block 403 may be filled with an insulating material. This concept is illustrated in FIG. 5C, which illustrates trenches 510, 510′ as being filled with an insulating material 511, 511′. Insulating material 511, 511′ may be formed by depositing and/or growing one or a combination of insulating materials within trenches 510, 510′. Non-limiting examples of suitable insulating materials that may be used as or in insulating material 511, 511′ include borophophosilicate glass, an insulating oxide such as SiOₓ (e.g., SiO₂), silica and/or silicates derived from a silicate precursor such as tetraethylorthosilicate (TEOS), a spin on polymer dielectric material, a spin-on silicon based polymeric dielectric material, combinations thereof, and the like. In any case, trenches 510, 510′ may be filled with insulating material 511, 511′ using any suitable process.

In some embodiments, trenches 510, 510′ may be filled by a multistep process in which the bulk of trenches 510, 510′ may be initially filled with BPSG, e.g., using chemical vapor deposition (CVD) or other suitable process. The depth of the initial BPSG fill may vary considerably, and may range from about 1000 to about 50,000 angstroms or more, depending on the depth of trenches 510, 510′. Without limiting the depth of the initial BPSG fill may range from about 10,000 to about 30,000 angstroms, such as about 18,000 to about 25,000 angstroms. Although high quality deposition of BPSG is possible (e.g. with a CVD or other process), in many instances cracks or other defects may be present in the BPSG fill. Left alone, such defects may negatively impact the performance of the through via channels describe herein. Therefore in some embodiments cracks and/or other defects in the BPSG fill (if any) may be filled by depositing one or more additional materials into trenches 510, 510′.

By way of example, in some embodiments defects in a BPSG fill may be at least partially filled by depositing tetraethylorthosilicate (TEOS) on the BPSG fill, e.g., by chemical vapor deposition. The deposited TEOS may then be converted to silicon dioxide by the application of heat, either alone or in combination with other processing steps understood in the art.

In some embodiments, the BPSG deposition noted above may result in the formation of a BPSG film within trenches 510, 510′ that exhibits tensile stress. As filling of trenches 510, 510′ with BPSG proceeds the buildup of tensile stress can be significant. To address this issue in some embodiments the TEOS deposition may be configured so as to relieve some or all of the tensile stress introduced by the BPSG deposition. This may be accomplished for example by depositing the TEOS in such a way that the resulting silicon oxide forms a film that exhibits tensile stress that is opposite to that of the stress exhibited by the BPSG fill. This may limit and/or prevent bowing of the wafer

During the BPSG and TEOS depositions, material may be deposited above and/or on the upper surface of alternating dielectric and conductive layers 504, 505. Therefore in some embodiments, an optional first polishing process such as chemical mechanical polishing may be executed to remove unwanted BPSG and SiO₂ and in some instances to planarize the surface of the alternating conductive and dielectric layers 504, 505. Following the optional first polishing process (or if the first polishing process is omitted) cracks or other defects may remain (or be otherwise introduced) in the fill of insulating material 511, 511′. In such instances, TEOS may be deposited again to fill such defects. Alternatively or additionally, another insulating material such as a spin on dielectric may be deposited to fill such defects. Following the additional deposition of TEOS and/or other insulating material, an optional second polishing process may be performed to remove unwanted material and/or to planarize the surface of the alternating conductive and dielectric layers 504, 505.

Following the deposition process, insulating material 511, 511′ may fill all or substantially all of trenches 510, 510′, such that an upper surface of insulating material 511, 511′ may be substantially coplanar with a surface of an uppermost one of conductive and dielectric layers 504, 505. In the embodiment shown in FIG. 5C, the upper surface of insulating material 511, 511′ is coplanar with a surface of an uppermost one of dielectric or conductive layers 504, 505.

Returning to FIG. 4, the method may proceed to block 405, wherein one or more channels may be formed in the insulating material formed pursuant to block 404. As noted above the present disclosure will focus on embodiments wherein a single channel 512, 512′ is formed in insulating material 511, 511′ but it should be understood that a plurality of channels (e.g., 2, 3, 4, 5, 6, etc.) may be formed in the insulating material 511, 511′ of each trench 510, 510′, depending on the dimensions of trench 510, 510′ and the characteristics of insulating material 511, 511′. In any case the concept of forming a channel in an insulating material is depicted in FIG. 5D, which illustrates the formation of a single channel 512, 512′ within insulating material 511, 511′.

Channel 512, 512′ may be formed using any suitable process known in the art, such as an etching or ablation process. Without limitation, in some embodiments channel 512, 512′ is preferably formed using a dry etching process such as but not limited to a contact etch process and a high aspect ratio trench (HART) process. Like the HART process that may be used to form trench 510, 510′, the dry etch process used to form channel 512, 512′ may be configured to aggressively etch the material(s) used to for insulating material 511, 511′ (e.g., BPSG, SiO₂, spin on dielectric, etc.), but may not etch or may not substantially etch the material of structure 509 (e.g., a conductor such as tungsten). Because the top dimension of channel 512, 512′ is much smaller than trench 510, 510′ however, the dry etch process used to form channel 512, 512′ may be configured to enable significantly higher aspect ratio etching than the HART process that may be used to form trench 510, 510′. In any case channel 512, 512′ may provide access to structure 509. As will be described later, channels 512, 512′ may be used to route one or more access lines from a region above the stack of dielectric and conductive layers 504, 505 to a region below the stack, e.g., to structure 509 (e.g., CUA circuitry).

Although the present disclosure envisions embodiments in which channel(s) 512, 512′ may be formed to any suitable dimensions, in some embodiments it may be desirable to control the dimensions of channel(s) 512, 512′ and in turn the thickness of insulating layer 511, 511′ remaining between the stack of alternating dielectric and conductive layers 504, 505 and channel(s) 512, 512′. This is particularly true in instances where channel(s) 512, 512′ will be filled or otherwise contain conductive material. In such instances it may be desirable to ensure that the thickness of insulating layer 511 remaining after the formation of channel(s) 512, 512′ is sufficient to electrically insulate the conductive fill that will be added to channel(s) 512, 512′ from the stack of alternating dielectric and conductive layers 504, 505, e.g., so as to prevent an electrical short. In this regard the thickness of insulating material 511, 511′ remaining after the formation of channel(s) 512, 512′ may vary widely. In some embodiments the thickness of insulating material 511, 511′ remaining after the formation of channel(s) 512, 512′ may range from about 90 to about 250 nanometers (nm), such as about 100 nm. Without limitation, the thickness of insulating material 511, 511′ remaining after the formation of channel(s) 512, 512′ is greater than or equal to about 100 nm. In FIGS. 5D-F channel(s) 512, 512′ are illustrated as having a tapered structure, such that a dimension (e.g., width) proximate the bottom of the channel is smaller than the corresponding dimension proximate the top of each channel. As such, channel(s) 512, 512′ may be understood to have a sidewall exhibiting a slope. The magnitude of the slope of the sidewall of channel(s) 512, 512′ may vary widely, and may be dictated by design and/or processing constraints. Without limitation, the slope of one or both of the sidewalls of channel(s) 512, 512′ may range from about 88 to about 89 degrees, relative to the top surface of structure 509. In some embodiments, the slope of channel(s) 512, 512′ may be the same or substantially the same as the slope of trenches 510, 510′.

Returning to FIG. 4 the method may proceed to block 406, wherein the channel(s) formed pursuant to block 405 may be metallized so as to form a conductive line there through. In this regard the present disclosure envisions various embodiments wherein channel(s) 512, 512′ may be filled with one or more materials, including at least one conductive material such as a conductive metal. In some embodiments, metallization is performed using a multistep process in which a barrier layer is deposited on the walls and/or bottom of channel(s) 512, 512′, after which one or more layers of conductive material (e.g., metal) are deposited on the barrier layer. In some embodiments deposition of the barrier layer is followed by the deposition of a single metal layer. In other embodiments deposition of the barrier layer is followed by deposition of a first metal layer and a second metal layer/fill.

The foregoing concepts are illustrated in FIGS. 5E and 5F. In particular, FIG. 5E illustrates an embodiment wherein barrier layers 513, 513′ are formed on the sidewalls and bottom of channels 512, 512′ Barrier layers 513, 513′ may be formed using any suitable process, such as but not limited to chemical vapor deposition, physical vapor deposition, electron beam deposition, atomic layer deposition, pulsed laser deposition, combinations thereof, and the like. Without limitation, barrier layers 513, 513′ are preferably formed via chemical vapor deposition.

Barrier layers 513, 513′ may be formed from any suitable barrier material or combination of barrier materials. Non-limiting examples of suitable materials that may be used as barrier layers 513, 513′ include barrier metals and metal nitrides such as titanium nitride, tantalum nitride, tungsten nitride, and tungsten. Without limitation, barrier layers 513, 513′ are preferably formed from titanium nitride that is deposited by chemical vapor deposition. Of course, other barrier materials may be used and are envisioned by the present disclosure.

The thickness of barrier layers 513, 513′ may vary widely. In some embodiments the thickness of barrier layers 513, 513′ ranges from about 1 to about 5000 Angstroms, such as about 1 to about 500 Angstroms, or even about 1 to about 100 Angstroms. Without limitation, barrier layers 513, 513′ preferably have a thickness in the range of about 25 to about 75 Angstroms, and in some embodiments there thickness is about 60 Angstroms. Following deposition of barrier layers 513, 513′, chemical mechanical polishing may be optionally carried out to ensure that barrier layers 513, 513′ are present only within channels 512, 512′. In any case, some portion of channel(s) 512, 512′ may remain after deposition of barrier layers 513, 513′, as shown in FIG. 5E. In other words, barrier layers 513, 513′ preferably only fill a portion of channel(s) 512, 512′.

As shown in FIG. 5F, metallization of channel(s) 512, 512′ may continue with the deposition of conductive material 514, 514′ within the remaining portion of channel(s) 512, 512′. As noted previously, conductive material 514, 514′ may include one or more types of conductive materials, which may be in layer form or intermixed with one another. In this regard a wide range of conductive materials may be used to form conductive material 514, 514′ include metals such as aluminum, copper, titanium, tungsten, conductive nitrides and oxides thereof, other conductive materials such as conductive polymers, polycrystalline silicon, etc., combinations thereof, and the like.

In some embodiments, conductive material 514, 514′ is in the form of a single fill including one or a combination of the foregoing materials. In other embodiments, conductive material 514, 514′ is in the form of a multilayer structure, wherein one or more layers of the foregoing conductive materials are initially formed, followed by or interleaved with the formation of one or more additional layers of the foregoing conductive materials. In some embodiments, conductive material 514, 514′ is formed by depositing a first metal layer (e.g., of titanium or another conductive material), followed by forming a second metal layer (e.g., of tungsten or another conductive material) on the first metal layer.

Conductive material 514, 514′ may be formed and/or deposited within the remaining portion of channel(s) 512, 512′ in any suitable manner, such as but not limited to chemical vapor deposition, physical vapor deposition, electron beam deposition, atomic layer deposition, pulsed laser deposition, combinations thereof, and the like. Without limitation, conductive material is preferably formed by chemical vapor deposition of a first metal layer (e.g., of titanium or another conductive material), followed by chemical vapor deposition of a second metal layer (e.g., of tungsten or another conductive material) on the first metal layer.

Following deposition of conductive material 514, 514′, chemical mechanical polishing (CMP) may be optionally performed to remove conductive material from an upper surface of the uppermost one of the stack of dielectric and conductive layers 504, 505, such that conductive material 514, 514′ may be isolated to within trenches 510, 510′ or more particularly to within channels 512, 512′ formed therein. In some embodiments, the surface of conductive material 514, 514′ is coplanar with the upper surface the upper surface of the uppermost one of the stack of dielectric and conductive layers 504, 505, as shown in FIG. 5F.

At this point the formation of the non-volatile memory may continue, e.g., by coupling one or more access lines to conductive material 514, 514′, so as to route such lines to structure 509, e.g., driving circuitry that may have been previously formed below a memory array and/or a peripheral region thereof. In this way, the access lines may be routed through the channel(s) 512, 512′. As noted previously, this may open up a wide variety of alternative routing configurations, in which access lines may be routed to underlying circuitry via one or more through vias. In some embodiments this may enable a large number of access lines to be routed and/or additional access lines to be added, without affecting or substantially affecting the block height and performance of the non-volatile memory. As such the technologies described herein are anticipated to be particularly useful in highly dense memory arrays, wherein large numbers of access lines need to be routed and the block height of the array is limited by design considerations and/or a standard.

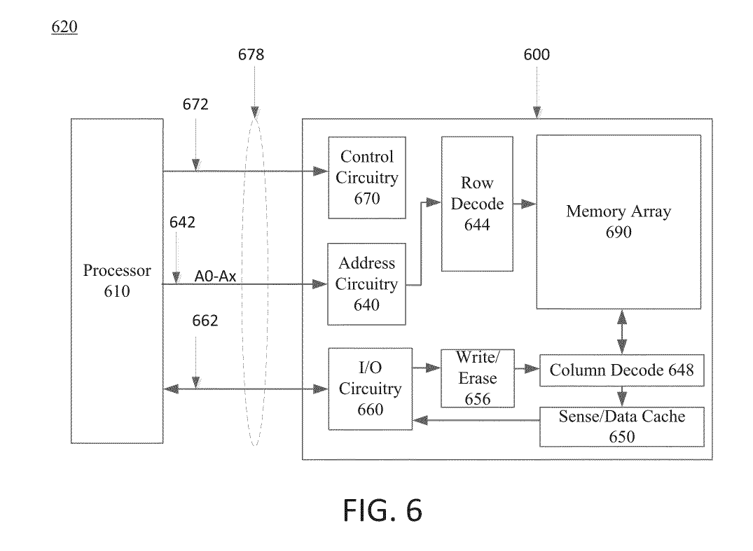

FIG. 6 is a functional block diagram of an electronic system having at least one memory device according to one or more embodiments of the present disclosure. The memory device 600 illustrated in FIG. 6 is coupled to a host such as a processor 610. The processor 610 may be a microprocessor or some other type of controlling circuitry. The memory device 600 and the processor 610 form part of an electronic system 620. The memory device 600 has been simplified to focus on features of the memory device that are helpful in understanding various embodiments of the present disclosure.

Memory device 600 includes one or more memory arrays 690 of memory cell that might be logically arranged in banks of rows and columns. According to one or more embodiments, memory array 690 may be configured as described above with respect to the memory arrays of FIGS. 1-3 and 5A-F. Accordingly, memory array 690 may be in the form of flash memory that include multiple banks and blocks of memory cells residing on a single or multiple die as part of the memory device 600

Address buffer circuit 640 may be provided to latch address signals provided on address input connections A0-AX 642. Address signals are received and decoded by row decoder 644 and column decoder 648 to access the memory array 690. Row decoder 644 may comprise driver circuits configured to drive the word lines, string select gates and one or more plane gates according to various embodiments of the present disclosure, for example. It will be appreciated by those skilled in the art, with the benefit of the present description, that the number of address input connections 642 may depend on the density and architecture of the memory array 690. That is, the number of address digits increases with both increased memory cell counts and increased bank and block counts, for example.

Memory device 600 may read data in memory array 690 by sensing voltage or current changes in the memory array columns using sense devices, such as sense/data cache circuitry 650. In some embodiments sense/data cache circuitry 650 is coupled to read and latch a row of data from memory array 690. Data input and output (I/O) buffer circuitry 660 may be included for bi-directional data communication over a plurality of data connections 662 with processor 610. Write/erase circuitry 656 may be provided to write data to or to erase data from the memory array 690.

Control circuitry 670 may be configured at least in part to implement various embodiments of the present disclosure, such as facilitating control of various gates as discussed above. In at least one embodiment control circuitry 670 may include a state machine. Control signals and commands may be sent by processor 610 to memory device 600 over command bus 672, Command bus 672 may transmit discrete or multiple command signals. Command signals transmitted over command bus 672 may be used to control the operations on the memory array 690, including data read, data program (e.g., write), and erase operations. Command bus 672, address bus 642 and data bus 662 may all be combined or may be combined in part to form a number of standard interfaces 678. For example, interface 678 between memory device 600 and the processor 610 may be a Universal Serial Bus (USB) interface. Interface 678 may also be a standard interface used with many hard disk drives and mother boards, such as but not limited to a peripheral component interface (PCI), a PCI express interface, a serial advanced technology attachment (SATA) or parallel advanced technology attachment (DATA), combinations thereof and the like as are known to those skilled in the art.

### EXAMPLES

The following examples pertain to further embodiments. The following examples of the present disclosure may comprise subject material such as a non-volatile memory and methods for making the same, as provided below.

### Example 1

One example of the technology of the present disclosure is a non-volatile memory, including: a memory array including a stack of alternating dielectric and conductive layers formed on an insulating layer, the memory array further including an array region and a peripheral region; a structure formed under at least one of the array region and peripheral region and electrically coupled to another component of the non-volatile memory; and a through array via formed in at least one of the array region and the peripheral region; wherein at least one access line of the memory array is routed through the through array via.

### Example 2

This example includes any or all of the features of example 1, wherein the through array via is formed in at least the peripheral region.

### Example 3

This example includes any or all of the features of example 1, wherein the memory array includes a vertical stack of memory cells.

### Example 4

This example includes any or all of the features of example 1, wherein the another component includes driver circuitry for driving at least one memory string of the memory array.

### Example 5

This example includes any or all of the features of example 4, wherein:

the memory array includes at least first and second memory arrays each of which comprise a plurality of memory cells; and

the driver circuitry is shared between the first and second memory arrays and is configured to drive the memory cells thereof.

### Example 6

This example includes any or all of the features of example 1, wherein the stack of alternating dielectric and conductive layers has an upper surface, and the through array extends from the upper surface to the structure.

### Example 7

This example includes any or all of the features of example 1, wherein the through array via includes at least one high aspect ratio trench.

### Example 8

This example includes any or all of the features of example 7, wherein at least one insulating material at least partially fills the trench.

### Example 9

This example includes any or all of the features of example 8, wherein the at least one insulating material is selected from the group consisting of borophosphosilicate glass, a non-conductive silicon oxide, a spin on dielectric material, and combinations thereof.

### Example 10

This example includes any or all of the features of example 9, wherein the at least one insulating material is a combination of borophosphosilicate glass, SiO₂, and a spun on dielectric material.

### Example 11

This example includes any or all of the features of example 8, wherein at least one channel is formed in the insulating material.

### Example 12

This example includes any or all of the features of example 11, wherein at least one conductive material is formed in the at least one channel.

### Example 13

This example includes any or all of the features of example 12, wherein the at least one conductive material is selected from the group consisting of aluminum, copper, titanium, tungsten, a conductive metal nitride, a conductive metal oxide, a conductive polymer, polycrystalline silicon, and combinations thereof.

### Example 14

This example includes any or all of the features of example 12, wherein the at least one conductive material is in the form of at least one first conductive layer and at least one second conductive layer deposited on the at least one first conductive layer.

### Example 15

This example includes any or all of the features of example 14, wherein the first conductive layer is titanium and the second conductive layer is tungsten.

### Example 16

This example includes any or all of the features of any one of examples 12 through 15, wherein a thickness between the insulating material and the channel is sufficient to electrically insulate the conductive material from the stack of alternating dielectric and conductive layers.

### Example 17

This example includes any or all of the features of any one of examples 12 and 13, further including at least one barrier layer formed between the at least one conductive material and the stack of alternating dielectric and conductive layers.

### Example 18

This example includes any or all of the features of example 17, wherein the at least one barrier layer is formed from a barrier material selected from the group consisting of titanium nitride, tantalum nitride, tungsten nitride, tungsten and combinations thereof.

### Example 19

This example includes any or all of the features of any one of examples 14 and 15, further including at least one barrier layer formed between the first conductive layer and the stack of alternating dielectric and conductive layers.

### Example 20

This example includes any or all of the features of example 19, wherein the at least one barrier layer is formed from a barrier material selected from the group consisting of titanium nitride, tantalum nitride, tungsten nitride, tungsten and combinations thereof.

### Example 21

This example includes any or all of the features of any one of example 1, wherein the at least one access line includes at least one of a source line, word line, select gate source line, and a select gate drain line.

### Example 22

According to this example there is provided a method of forming a non-volatile memory, including: providing a memory array including a stack of alternating dielectric and conductive layers formed on an insulating layer, the memory array further including an array region and a peripheral region; forming at least one through array via in at least one of the array region and peripheral region, the through array via extending from an upper surface of the stack of alternating dielectric and conductive layers to a structure under at least one of the array region and the peripheral region, the structure being electrically coupled to an another component of the non-volatile memory; wherein the through array via is configured to enable electrical coupling of at least one access line of the memory array to the structure.

### Example 23

This example includes any or all of the features of example 22, wherein the memory array includes a vertical stack of memory cells.

### Example 24

This example includes any or all of the features of example 22, wherein the another component includes driver circuitry for driving at least one memory string of the memory array.

### Example 25

This example includes any or all of the features of example 24, wherein: the memory array includes at least first and second memory arrays each of which comprise a plurality of memory cells; and the driver circuitry is shared between the first and second memory arrays and is configured to drive the memory cells thereof.

### Example 26

This example includes any or all of the features of example 23, wherein the stack of alternating dielectric and conductive layers has an upper surface, and the through array extends from the upper surface to the structure.

### Example 27

This example includes any or all of the features of example 22, wherein forming the at least one through array via includes forming at least one high aspect ratio trench extending from an upper surface of the alternating dielectric and conductive layers to the structure.

### Example 28

This example includes any or all of the features of example 27, wherein forming the at least one high aspect ratio trench includes etching the alternating dielectric and conductive layers with a dry etching process.

### Example 29

This example includes any or all of the features of example 27, wherein forming the at least one through array via further includes filling the at least one high aspect ratio trench with at least one insulating material.

### Example 30

This example includes any or all of the features of example 25, wherein the at least one insulating material is selected from the group consisting of borophosphosilicate glass, a non-conductive silicon oxide, a spin on dielectric material, and combinations thereof.

### Example 31

This example includes any or all of the features of example 30, wherein the at least one insulating material is a combination of borophosphosilicate glass, SiO₂, and a spun on dielectric material.

### Example 32

This example includes any or all of the features of example 31, wherein filling the at least one high aspect ratio trench includes: depositing borophosphosilicate glass in the at least one high aspect ratio trench; depositing tetraorthosilicate on the borophosphosilicate glass via chemical vapor deposition; converting the tetraorthosilicate to silica; and depositing a spin on dielectric material on at least one of the silica and the borophosphosilicate glass.

### Example 33

This example includes any or all of the features of example 29, wherein forming the at least one through array via further includes forming at least one channel in the at least one insulating material.

### Example 34

This example includes any or all of the features of example 33, wherein forming the at least one channel includes etching the at least one insulating material such that the channel extends from an upper surface of the at least one insulating material to the component.

### Example 35

This example includes any or all of the features of example 34, wherein etching the at least one insulating material is performed with a dry etching process.

### Example 36

This example includes any or all of the features of example 33, wherein forming the at least one through array via further includes filling the at least on channel with at least one conductive material.

### Example 37

This example includes any or all of the features of example 36, wherein the at least one conductive material is selected from the group consisting of aluminum, copper, titanium, tungsten, a conductive metal nitride, a conductive metal oxide, a conductive polymer, polycrystalline silicon, and combinations thereof.

### Example 38

This example includes any or all of the features of example 36, wherein the at least one conductive material is in the form of at least one first conductive layer and at least one second conductive layer deposited on the at least one first conductive layer.

### Example 39

This example includes any or all of the features of example 38, wherein the first conductive layer is titanium and the second conductive layer is tungsten.

### Example 40

This example includes any or all of the features of any one of examples 36 to 39, wherein a thickness between the insulating material and the channel is sufficient to electrically insulate the conductive material from the stack of alternating dielectric and conductive layers.

### Example 41

This example includes any or all of the features of any one of examples 36 and 37, further including forming at least one barrier layer between the at least one conductive material and the stack of alternating dielectric and conductive layers.

### Example 42

This example includes any or all of the features of example 41, wherein the at least one barrier layer is formed from a barrier material selected from the group consisting of titanium nitride, tantalum nitride, tungsten nitride, tungsten and combinations thereof.

### Example 43

This example includes any or all of the features of example 41, wherein forming the at least one barrier layer is performed using at least one of chemical vapor deposition, physical vapor deposition, electron beam deposition, atomic layer deposition, and pulsed laser deposition.

### Example 44

This example includes any or all of the features of any one of examples 38 and 39, further including forming at least one barrier layer between the first conductive layer and the stack of alternating dielectric and conductive layers.

### Example 45

This example includes any or all of the features of example 44, wherein the at least one barrier layer is formed from a barrier material selected from the group consisting of titanium nitride, tantalum nitride, tungsten nitride, tungsten and combinations thereof.

### Example 46

This example includes any or all of the features of example 44, wherein forming the at least one barrier layer is performed using at least one of chemical vapor deposition, physical vapor deposition, electron beam deposition, atomic layer deposition, and pulsed laser deposition.

### Example 47

This example includes any or all of the features of example 22, wherein the at least one access line includes at least one of a source line, word line, select gate source line, and a select gate drain line.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

What is claimed is:

1. A non-volatile memory, comprising:
a memory array comprising a stack of alternating dielectric and conductive layers formed on an insulating layer, the memory array further comprising an array region and a peripheral region;
a structure formed under at least one of the array region and peripheral region and electrically coupled to another component of said non-volatile memory; and
a through array via formed in at least one of said array region and said peripheral region;
wherein at least one access line of said memory array is routed through said through array via.

2. The non-volatile memory of claim 1, wherein said through array via is formed in at least said peripheral region.

3. The non-volatile memory of claim 1, wherein said another component comprises driver circuitry for driving at least one memory string of said memory array.

4. The non-volatile memory of claim 3, wherein:
said memory array comprises at least first and second memory arrays each of which comprise a plurality of memory cells; and
said driver circuitry is shared between said first and second memory arrays and is configured to drive the memory cells thereof.

5. The non-volatile memory of claim 4, wherein:
said memory array comprises at least first and second memory arrays each of which comprise a plurality of memory cells; and
said driver circuitry is shared between said first and second memory arrays and is configured to drive the memory cells thereof.

6. The non-volatile memory of claim 1, wherein:
said stack of alternating dielectric and conductive layers has an upper surface;
said through array via comprises at least one high aspect ratio trench that extends from said upper surface to said structure; and
at least one insulating material at least partially fills said trench.

7. The non-volatile memory of claim 6, wherein said at least one insulating material is a combination of borophosphosilicate glass, SiO₂, and a spun on dielectric material.

8. The non-volatile memory of claim 6, wherein:
at least one channel is formed in said insulating material; and
at least one conductive material is formed in said at least one channel.

9. The non-volatile memory of claim 8, wherein said at least one conductive material is in the form of at least one first conductive layer and at least one second conductive layer deposited on the at least one first conductive layer.

10. The non-volatile memory of claim 8, further comprising at least one barrier layer formed between said at least one conductive material and said stack of alternating dielectric and conductive layers.

11. The non-volatile memory of claim 10, wherein said at least one barrier layer is formed from a barrier material selected from the group consisting of titanium nitride, tantalum nitride, tungsten nitride, tungsten and combinations thereof.

12. The non-volatile memory of claim, 9, further comprising at least one barrier layer formed between said first conductive layer and said stack of alternating dielectric and conductive layers, wherein said at least one barrier layer is formed from a barrier material selected from the group consisting of titanium nitride, tantalum nitride, tungsten nitride, tungsten and combinations thereof.

13. The non-volatile memory of claim 1, wherein said at least one access line comprises at least one of a source line, word line, select gate source line, and a select gate drain line.

14. A method of forming a non-volatile memory, comprising:
providing a memory array comprising a stack of alternating dielectric and conductive layers formed on an insulating layer, the memory array further comprising an array region and a peripheral region;
forming at least one through array via in at least one of said array region and peripheral region, the through array via extending from an upper surface of said stack of alternating dielectric and conductive layers to a structure under at least one of the array region and the peripheral region, the structure being electrically coupled to an another component of said non-volatile memory;
wherein the through array via is configured to enable electrical coupling of at least one access line of said memory array to said structure.

15. The method of claim 14, wherein said memory array comprises a vertical stack of memory cells.

16. The method of claim 14, wherein;
said another component comprises driver circuitry for driving at least one memory string of said memory array;
said memory array comprises at least first and second memory arrays each of which comprise a plurality of memory cells; and
said driver circuitry is shared between said first and second memory arrays and is configured to drive the memory cells thereof.

17. The method of claim 15, wherein:
said stack of alternating dielectric and conductive layers has an upper surface, and said through array extends from said upper surface to said structure; and
forming said at least one through array via comprises forming at least one high aspect ratio trench extending from an upper surface of said alternating dielectric and conductive layers to said structure.

18. The method of claim 17, wherein forming said at least one high aspect ratio trench comprises etching said alternating dielectric and conductive layers with a dry etching process.

19. The method of claim 18, wherein forming said at least one through array via further comprises filling said at least one high aspect ratio trench with at least one insulating material.

20. The method of claim 19, wherein filling said at least one high aspect ratio trench comprises:
depositing borophosphosilicate glass in said at least one high aspect ratio trench;
depositing tetraorthosilicate on said borophosphosilicate glass via chemical vapor deposition;
converting said tetraorthosilicate to silica; and
depositing a spin on dielectric material on at least one of said silica and said borophosphosilicate glass.

21. The method of claim 19, wherein forming said at least one through array via further comprises forming at least one channel in said at least one insulating material that extends from an upper surface of said at least one insulating material to said component.

22. The method of claim 21, wherein forming said at least one through array via further comprises filling said at least on channel with at least one conductive material.

23. The method of claim 22, wherein said at least one conductive material is in the form of at least one first conductive layer and at least one second conductive layer deposited on the at least one first conductive layer.

24. The non-volatile of claim 24 wherein said first conductive layer is titanium and the second conductive layer is tungsten.

25. The method of claim 22, further comprising forming at least one barrier layer between said at least one conductive material and said stack of alternating dielectric and conductive layers.
